(19) United States
(12) Patent Application Publication
(10) Pub. No.: US 2011/0050912 A1
(43) Pub. Date: Mar. 3, 2011

(54) IMAGE CAPTURING DEVICE AND METHOD

(75) Inventors: HOU-HSIEN LEE, Tu-Cheng (TW); CHANG-JUNG LEE, Tu-Cheng, Taipei Hsien (TW); CHIH-PING LO, Tu-Cheng (TW)

(73) Assignee: HON HAI PRECISION INDUSTRY CO., LTD., Tu-Cheng (TW)

(21) Appl. No.: 12/641,587

(22) Filed: Dec. 18, 2009

(30) Foreign Application Priority Data
Aug. 28, 2009 (CN) 200910306248.X

(51) Int. Cl. H04N 5/225; H01L 31/0232

(52) U.S. Cl. 348/207.1; 250/227.2; 348/E05.024

(57) ABSTRACT

A method for capturing images includes setting a capturing mode and a capturing schedule for a plurality of lenses of an image capturing device, controlling each lens to capture images according to the capturing schedule based on different magnifications. The method further sends the plurality of images to a monitor computer, and stores the plurality of images in a file by the monitor computer.

### BACKGROUND

1. Technical Field

Embodiments of the present disclosure relate to image capturing technology, and particularly to an image capturing device and method.

2. Description of Related Art

In recent years, image capturing devices (e.g., closed circuit television (CCTV)) may include a plurality of lenses to perform security surveillance by capturing a plurality of images of a specified space at the same time, sending the plurality of images to a surveillance monitoring computer, and storing the plurality of images in a storage device. However, since the plurality of images are stored separately using a plurality of files, a user must open the files one by one to view all the images, which is inconvenient and time consuming.

### BRIEF DESCRIPTION OF THE DRAWINGS

FIG. 1 is a schematic diagram of one embodiment of a structure of a plurality of lens of an image capturing device in a single level mode.

FIG. 2 is a schematic diagram of one embodiment of a structure of the plurality of lenses of the image capturing device in a cylindrical mode.

FIG. 3 is a schematic diagram of one embodiment of a structure of the plurality of lenses of the image capturing device in a spherical mode.

FIG. 4 is a flowchart of one embodiment of a method for capturing images.

FIG. 5 is a schematic diagram of one embodiment of capturing a plurality of images with different magnifications.

FIG. 6 is a schematic diagram of one embodiment of a file storing the plurality of images of different magnification in FIG. 5.

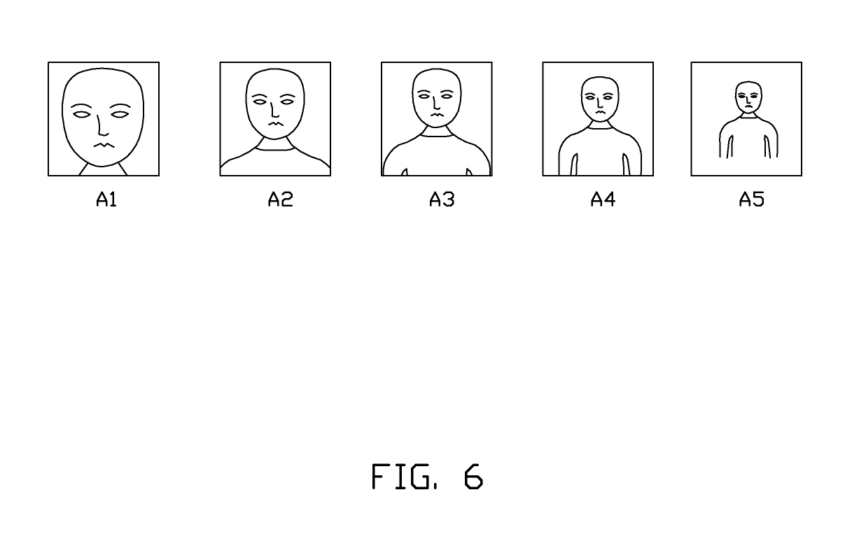

### DETAILED DESCRIPTION

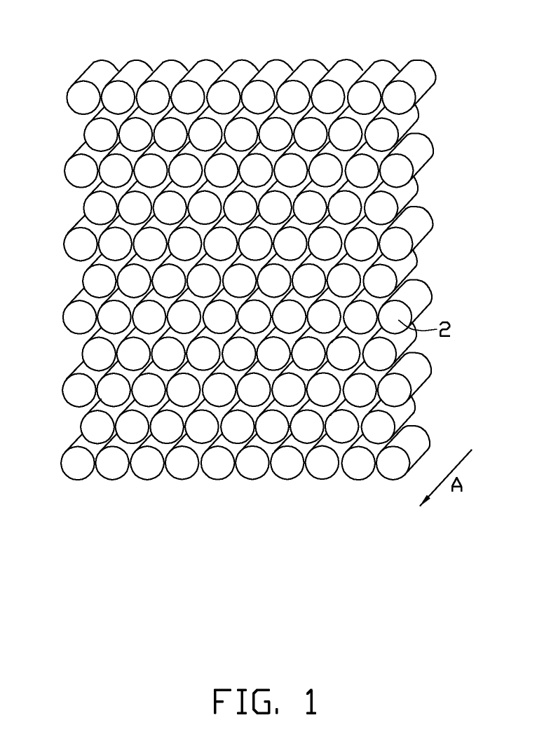

FIG. 1 is a schematic diagram of one embodiment of a structure of a plurality of lenses 2 of an image capturing device in a single level mode. In the single level mode, the plurality of lenses 2 of the image capturing device are aligned on the same plane, and each lens 2 is set at a different magnification (i.e., zoom ratio) from the other lenses 2. Referring to FIG. 1, a direction of an arrow “A” represents a capturing direction of the plurality of lenses 2. In one embodiment, the image capturing device includes more than two lenses 2.

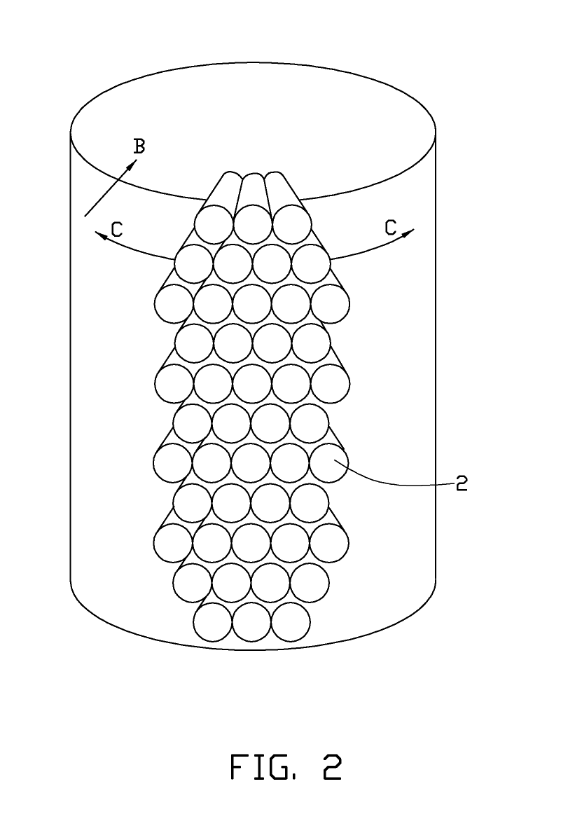

FIG. 2 is a schematic diagram of one embodiment of a structure of a plurality of lenses 2 of an image capturing device in a cylindrical mode. In the cylindrical mode, the plurality of lenses 2 of the image capturing device are aligned cylindrically. As in the single level mode, the magnification of each of the lenses 2 is different. Referring to FIG. 2, a direction of an arrow “B” represents a capturing direction of the plurality of lenses 2, a direction of an arrow “C” represents an aligned direction of the plurality of lenses 2 in the cylindrical mode.

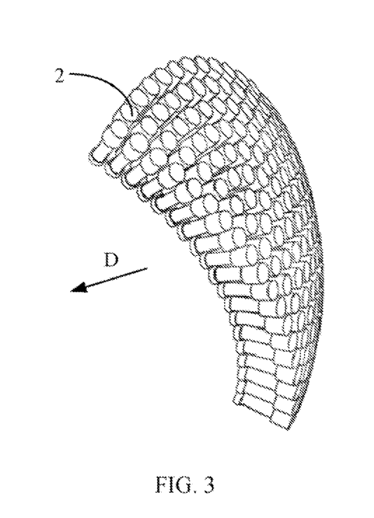

FIG. 3 is a schematic diagram of one embodiment of a structure of a plurality of lenses 2 of an image capturing device in a spherical mode. In the spherical mode, the plurality of lenses 2 of the image capturing device are aligned spherically. As in the other modes, the magnification of each of the lenses 2 is different. Referring to FIG. 3, a direction of an arrow “D” represents a capturing direction of the plurality of lenses 2.

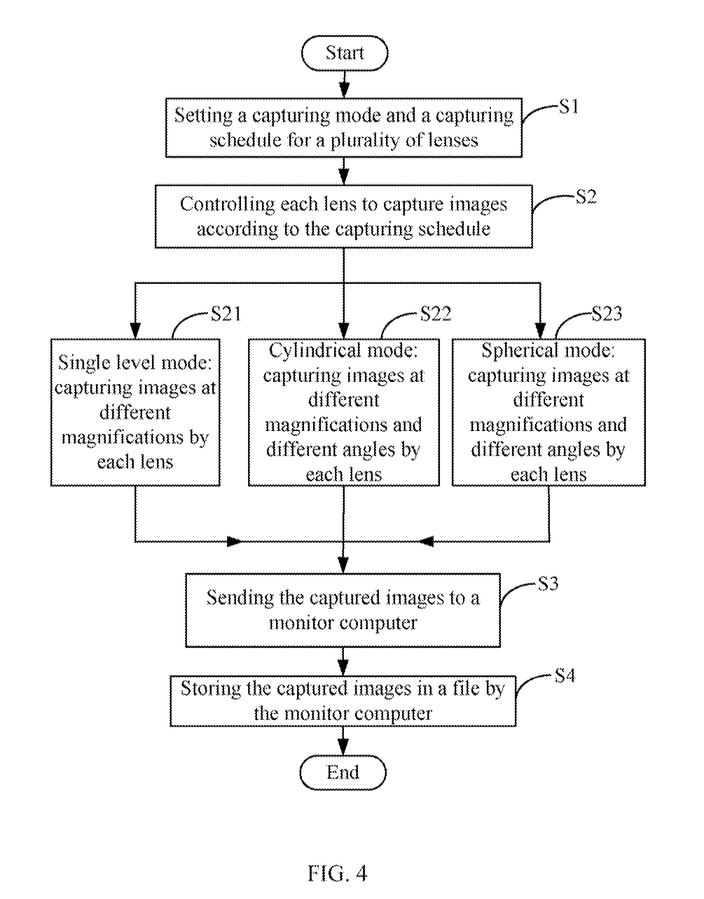

FIG. 4 is a flowchart of one embodiment of a method for capturing images. Depending on the embodiment, additional blocks may be added, others removed, and the ordering of the blocks may be changed.

In block S1, a capturing mode and a capturing schedule of the plurality of lenses 2 of the image capturing device are set manually. In one embodiment, the capturing mode of the plurality of lenses 2 may be a single level mode (refers to FIG. 1), a cylindrical mode (refers to FIG. 2), or a spherical mode (refers to FIG. 3). In the cylindrical mode and the spherical mode, the plurality of lenses 2 of the image capturing device are aligned on the same curved surface.

In block S2, the image capturing device controls the lenses 2 to capture images according to the capturing schedule according to blocks S21, S22, or S23. Block S21 is processed if the capturing mode of the plurality of lenses 2 is the single level mode. Block S22 is processed if the capturing mode of the plurality of lenses 2 is the cylindrical mode. Block S23 is processed if the capturing mode of the plurality of lenses 2 is the spherical mode.

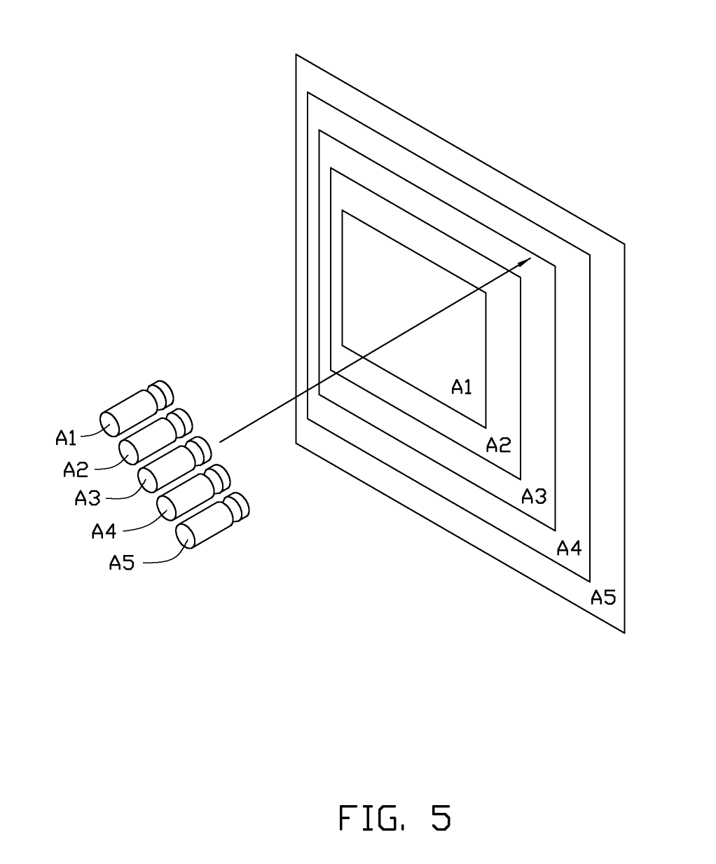

In block S21, the plurality of lenses 2 of the image capturing device capture images at different magnifications according to the capturing schedule at the same time (refers to FIG. 5). That is to say, the plurality of lenses 2 capture the same image, but at different magnifications all at the same time.

In block S22, the plurality of lenses 2 of the image capturing device capture images at different magnifications from different angles according to the capturing schedule at the same time.

In block S23, the plurality of lenses 2 of the image capturing device capture images at different magnifications from different angles according to the capturing schedule at the same time.

In block S3, the image capturing device sends the plurality of images to a monitor computer for security monitoring purposes.

In block S4, the monitor computer stores the plurality of images in a single file, so that a user only need to open one file to view all the images at the same time. In one embodiment, the plurality of images stored in the single file are arranged one by one for the user to view all the images at the same time.

It should be emphasized that the above-described embodiments of the present disclosure, particularly, any embodiments, are merely possible examples of implementations, merely set forth for a clear understanding of the principles of the disclosure. Many variations and modifications may be made to the above-described embodiment(s) of the disclosure without departing substantially from the spirit and principles of the disclosure. All such modifications and variations are intended to be included herein within the scope of this disclosure and the present disclosure and protected by the following claims.

What is claimed is:

1. An image capturing device comprising a plurality of lenses, wherein the plurality of lenses are aligned on a same plane or a same curved surface, and magnifications of each of the plurality of lenses are different.

2. The image capturing device according to claim 1, wherein the plurality of lenses on the same curved surface are aligned in a cylindrical mode or a spherical mode.

3. The image capturing device according to claim 2, wherein the plurality of lenses of the image capturing device are aligned cylindrically in the cylindrical mode.

4. The image capturing device according to claim 2, wherein the plurality of lenses of the image capturing device are aligned spherically in the spherical mode.

5. A method for capturing images, comprising:
providing an image capturing device comprising a plurality of lenses, wherein the plurality of lenses are aligned on a same plane or a same curved surface, and magnifications of each of the plurality of lenses are different;
setting a capturing mode and a capturing schedule of the plurality of lenses;
controlling each lens of the image capturing device to capture images according to the capturing schedule; and
sending the plurality of images to a monitor computer.

6. The method according to claim 5, further comprising: storing the plurality of images in a single file by the monitor computer.

7. The method according to claim 5, wherein the plurality of lenses on the same curved surface are aligned in a cylindrical mode or a spherical mode.

8. The method according to claim 7, wherein the plurality of lenses of the image capturing device are aligned cylindrically in the cylindrical mode.

9. The method according to claim 7, wherein the plurality of lenses of the image capturing device are aligned spherically in the spherical mode.

10. The method according to claim 5, wherein controlling each lens of the image capturing device to capture images according to the capturing schedule comprises:
capturing images at different magnifications by each lens of the image capturing device according to the capturing schedule, if the plurality of lenses of the image capturing device are aligned on the same plane; and
capturing images at different magnifications from different angles by each lens of the image capturing device according to the capturing schedule, if the plurality of lenses are aligned on the same curved surface.
